(19) United States
(12) Patent Application Publication
(10) Pub. No.: US 2014/0264684 A1
(43) Pub. Date: Sep. 18, 2014

(54) PHOTOCONDUCTIVE SEMICONDUCTOR SWITCH

(71) Applicants: Rabi S. Bhattacharya, Beavercreek, OH (US); Howard Blane Evans, JR., Dayton, OH (US)

(72) Inventors: Rabi S. Bhattacharya, Beavercreek, OH (US); Howard Blane Evans, JR., Dayton, OH (US)

(73) Assignee: UES, INC., Dayton, OH (US)

(21) Appl. No.: 14/202,307

(22) Filed: Mar. 10, 2014

Related U.S. Application Data
(60) Provisional application No. 61/781,095, filed on Mar. 14, 2013.

(51) Int. Cl. H01L 31/09; H01L 31/0304

(52) U.S. Cl. CPC H01L 31/09; H01L 31/0304
USPC 257/431

(57) ABSTRACT

A photoconductive semiconductor switch comprising a photoconductive GaAs substrate having a pair of spaced metal contacts on a surface thereof, the spaced metal contacts opposite ends of a switching gap, the switching gap having a plurality of lateral current flow preventing channels therein, the channels being formed by ion implantation of the GaAs substrate in the channels.

### CROSS-REFERENCE TO RELATED APPLICATIONS

This application claims the benefit of U.S. Provisional Application 61/781,095 filed Mar. 14, 2013.

### STATEMENT REGARDING FEDERALLY SPONSORED RESEARCH OR DEVELOPMENT

This invention was supported by the government under Contract No. HDTRA1-11-P-0021 awarded by the Defense Threat Reduction Agency/CXC. The government has certain rights in the invention.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 depicts a GaAs PCSS (photoconductive semiconductor switch) with multiple channels for current conduction according to one or more embodiments shown and described herein;

FIG. 2 depicts an example of a laminar contact for GaAs PCSS according to one or more embodiments shown and described herein;

FIG. 3 is a graph showing a computer simulation of the implanted ion distribution in GaAs based on data from Table 1 according to one or more embodiments shown and described herein;

FIG. 4 is an image of the multi-channel conduction with 500 μm/500 μm doped GaAs sample at 34 kV pulse charged voltage according to one or more embodiments shown and described herein;

### DETAILED DESCRIPTION

High gain optically triggered photoconductive semiconductor switches (PCSS) enable future nuclear weapon effects (NWE) experimentation capabilities and concepts for the active interrogation of special nuclear materials (SNM). Semiconductors such as silicon carbide (SiC), gallium nitride (GaN) and semi-insulating gallium arsenide (GaAs) show photoconductivity upon illuminating the surface of the semiconductor material with an optical source whose photon energy is greater than the bandgap energy of these materials, thus enabling the development of PCSS devices from these materials. In one embodiment, the triggering radiation generates holes and electrons in the GaAs that produce a current under the high electrical bias voltage. PCSS devices fabricated from these semiconductors have demonstrated hold-off voltages exceeding 100 kV with turn on times of about 0.35 ns and timing jitter of about 0.1 ns. Unlike most photo-conductive semiconductors that only conduct as long as they are illuminated by enough light to generate current carriers, GaAs PCSS devices have the advantage of exhibiting regenerative high-gain; once the device is turned on by a short laser pulse, they remain conducting through a stable electron avalanche process. In one embodiment, GaAs PCSS are constructed using semi-insulating (SI) single crystals of high resistivity greater than 10⁷ Ohm-cm. Metal contacts are used to connect the switch to an energy source and a load. These switches exhibit high gain at electric fields above 4 to 6 kV/cm.

One problem with GaAs PCSS is that when uniformly illuminated the current becomes filamentary or “lightning-like.” In some cases the branching filamentary channel widths are 15 to 300 micrometers. The filaments can have current densities up to MA/cm² . The filamentary nature of this current impacts negatively the operational lifetime of the switches due to extremely high current densities causing localized heating of the conducting channel, causing damage in the semiconductor-metal interface, and also damage in the GaAs bulk material some distance away from the contacts. One major damage mechanism appears to be contact erosion resulting in higher on-state resistance and excessive voltage drop, ultimately causing the switch to cease functioning. Thus, in order to increase the life of these switches one has to find ways to increase the life of the switches with current per filament limited to less than 25 A for short pulses (less than 100 ns) in order to have long lifetimes (greater than 10⁷ shots). This limit is set by the localized heating of the filamentary conducting channel and the need to keep the temperature below the melting point.

It has been shown that the problem can be solved by illuminating the surface of one embodiment of a switch with narrow lines of laser light bridging the switching gap and spaced about 300 micrometers apart. This technique allows multiple parallel channels to form and remain separate throughout the conduction interval. However, this requirement limits the overall current density and requires complex, expensive, and inefficient laser triggering optics. A new approach to deal with this problem of the filamentary nature of the conduction current is needed. The solution may be attained by forming “dead bands” between conduction channels to prevent lateral current flow and the subsequent merging of neighboring filamentary channels.

One objective is to advance the state of the art of high-gain optically- triggered switches by increasing the current density (e.g., to greater than 1000 A/cm²) and voltage hold-off (e.g., to greater than 67 kV/cm or greater than 100 kV total) capabilities of complete switch assemblies; allow simple laser illumination; function in oil immersion; have rise-times and timing jitter less than 0.3 ns; and long lifetimes.

By controlling the formation and number of parallel filaments generated simultaneously to share the current such that the peak current density and damage to the switch can be reduced. The device may produce “dead bands” between the filamentary channels in GaAs that will allow the formation of multiple filaments and prevent lateral current flow between adjacent filaments. The “dead bands” can be produced by introducing lattice defect damage in the GaAs crystal using high energy (MeV) ion implantation. The spacing and width of the channels are designed to allow high switched current levels simultaneously with high longevity. The switch is shown schematically in FIG. 1. The switch 10 includes a semiconductor substrate 12. While GaAs is used in one embodiment, other semiconductors used to form PCSS can be used. A pair of contacts 14, 16 are formed on the surface 18 of the substrate 12. The space between the contacts 14, 16 constitutes the gap. Parallel ion implanted barrier channels 20 are spaced apart and run the length of the gap between the contacts when the switch is illuminated. The channels 24 carry current across the switch 10.

Masking of regions on the GaAs PCSS may be done to prevent filaments to form multiple, current-sharing and linear filaments. Uniform illumination of the masked, i.e. doped with “dead bands,” GaAs switch with unmasked laser beam 25 crossing the insulating gap produces multiple, linear, current-sharing filaments. The trade-off with this approach is a slight increase in the laser energy requirement. With a masked switch, some of the optical trigger energy will be deposited on the masked region between the filaments, which will typically be more or less the same as the unmasked lines to avoid intersecting, non-uniform current-sharing filament formation.

GaAs PCSS's are designed and fabricated using both as-received (undoped) and high energy ion implanted GaAs samples then tested in the PCSS experiments. Three and four inch diameter GaAs wafers with resistivity greater than 10⁷ Ohm-cm were procured. Wafers were cut into 1.0×0.5 inch and 1.5×0.5 inch pieces.

In one embodiment, the GaAs PCSS prototypes may have a gap of about 20 mm or about 10-30 mm, parallel channels (24) about 500-1000 μm separated by about 200-500 μm ion implanted dead bands (20) or about 100-700 μm dead bands (20). Channels with smaller widths and separations can be designed and implemented for increasing the number of channels in a given width of the switch, thus resulting in higher switch current. In order to create dead bands by damaging the GaAs crystal lattice using high energy ion irradiation, a stainless steel mask with laser etching is used. Masking can also be done by standard lithography and patterning with a layer of a photoresist as used in integrated device fabrication processes.

In one embodiment the metallic contacts 14, 16 may be fabricated by sequential deposition of Ni, Ge and Au layers of thicknesses about 50, 200 and 800 Å, respectively, as shown schematically in FIG. 2. The deposition was done by using e-beam evaporation. This contact construction is disclosed in U.S. Pat. No. 5,309,022 which is herein incorporated by reference in its entirety particularly with respect to the make-up and construction of the contacts. The metallic layers, after deposition, were annealed at 425° C. for 5 min in inert atmosphere. Contacts were also made with sequential deposition of Si, Au and Ni and then annealed at 425° C. for 5 min for a few samples.

Ion irradiations of GaAs samples with metallic contacts may be done using the 1.7 MV terminal voltage tandem (Tandetron™) accelerator. Multiple energies, 0.25 to 3.7 MeV oxygen ions were used to create the damage bands in one case. The ion implantation schedule was used and developed for Heterojunction Bipolar Transistor (HBT) device isolation that has been implemented for HBT fabrication. The schedule is shown in Table 1 below. An additional 0.25 MeV Ag⁺ ion implant for creating excess damage near the surface owing to the much heavier mass of Ag compared to O was used. A simulation of the depth distribution of the implanted ions is shown in FIG. 3. The damage distribution follows closely to the ion depth distribution.

TABLE 1
Ion Implantation Schedule

| | Energy | | |
|---|---|---|---|
| Ion | (MeV) | Ion Charge | Dose ions/cm² |
| Oxygen | 0.25 | +1 | 1.00 × 10¹³ |
| Oxygen | 0.37 | +1 | 1.60 × 10¹³ |
| Oxygen | 0.60 | +1 | 2.50 × 10¹² |
| Oxygen | 1.00 | +1 | 2.50 × 10¹² |
| Oxygen | 1.50 | +1 | 2.50 × 10¹² |
| Oxygen | 2.00 | +1 | 2.50 × 10¹² |
| Oxygen | 2.50 | +2 | 2.50 × 10¹² |
| Oxygen | 3.10 | +2 | 2.50 × 10¹² |
| Oxygen | 3.70 | +3 | 2.50 × 10¹² |
| Silver | 0.25 | +1 | 1.00 × 10¹³ |

### EXAMPLE

A GaAs sample holder for the switch was made from Lexan (Polycarbonate) plates. In one embodiment it consisted of two 4×4×0.25 inch plates. The GaAs switch rests on one plate and the other sheet carries beryllium-copper finger (spring) contacts that press on the contacts attached to the plate. The electrical contacts were made with copper strips welded to the finger electrodes, in which a copper foil passed through the slots and re-flow soldered to the springy beryllium-copper finger electrodes. The contacts overhang protrusions, allowing the contacts to bend upward about 0.030 inches as they touch the surface of the GaAs device when the cover is in place. The protrusions with the contact strips attached do not touch the surface of the GaAs device: there is a clearance allowance of about 0.01 inches. Although the contacts are capable of bending about 0.04 inches before the contact surface reaches the plane of the contact strip, the design requires them to bend only about 0.03 inches. Two spring beryllium-copper fingers were used as the electrodes. A tunable laser of wavelength range 400 nm to 1200 nm with output energy of 40 mJ and pulse width of 10 ns was used for testing these PCSS's.

The laser was attenuated and expanded to about 5 cm in diameter. It delivered about 1 mJ energy to the GaAs sample. The laser settings were controlled by a PC. A gated, intensified CCD camera, made by Princeton Instruments, was used to image the IR emissions from the switch current channels 20 in the GaAs samples. The images were taken about 15 ns after the laser pulse with a gating time of 2 μs. Camera settings were also controlled by a PC. The current waveforms of the switch samples and timing of the laser and camera were acquired by a 100 MHz oscillator scope. The DC-charged LCR circuitry and two high-voltage pulsers were used to conduct the photo-switch experiments. An un-doped GaAs sample has been tested by using a DC-charged LCR circuit, which was charged up to about 18 kV.

While certain embodiments of the invention have been illustrated using oxygen and silver ions for ion implantation to form the lateral flow preventing (“dead bands”) channels, those skilled in the art will recognize that other ions can be used to disrupt N-type or P-type holes in the semiconductor and obtain dead bands to prevent filamentary currents.

There are two work modes of PCSS, namely, a linear mode and a nonlinear mode. Linear mode involves a lower biased electrical field. In this mode, a semiconductor absorbing one photon will generate an electron hole pair and the output current quickly extinguishes as soon as the laser pulse has elapsed. In nonlinear mode, the biased electrical field across the PCSS is often higher. When the energy of the trigger is over a threshold value for example, greater than about 1 mJ for 18 kV GaAs PCSS, the current output from the PCSS will continue to flow in filaments even though the triggering laser is turned off. This mode is also called the “lock-on” or “avalanche” mode. In such an avalanche mode, the carriers in the semiconductor material are increased rapidly due to the high biased electrical field. This means that one photon can generate more than one carrier. Under nonlinear mode, the laser pulse only plays a role of triggering. If the electrical circuit can supply enough power, the PCSS remains in an “open” state after the laser pulse is extinguished. Under this mode, low laser power is required to open the switch compared with the linear mode. So a small size laser, such as semiconductor diode laser, may be used to trigger the PCSS, which makes the PCSS useful for a wide range of applications.

The GaAs samples were about 1 cm wide and the anode-cathode gap was about 1.5 cm. Two photo-conduction modes at relatively low and high triggering laser energy was produced, respectively, while keeping the DC charge voltage at about 18 kV. At a low laser energy (less than 10 μJ), the conduction current is low in amplitude (less than 10A) and oscillates with the periods of 10 ns. The IR photo-emissions from the GaAs sample were not produced at this low laser energy. This is the linear photo-conduction mode. It indicates that there exists not only a threshold of bias electric field, but also a threshold of optical energy for the transition of the PCSS from linear mode to non-linear mode.

A trigger laser energy of about 1 mJ produced conduction currents as high as 300 A at a DC charging voltage of 18 kV.

The doped GaAs samples have about 10-30 MΩ resistance across the 1.5 cm anode-cathode gap due to the O⁺ and Ag⁺ ion beam irradiation. A pulse charged 35 kV, about 100 ns electric circuit was used in the 500 μm×500 μm doped GaAs sample tests to produce up to 12 uniform distributed conduction current channels, as shown in FIG. 4.

Two high-voltage trigger pulsers with open circuit voltage of 50 and 100 kV were used to test the high voltage hold-off of the GaAs switch sample. The peak voltage at the GaAs sample was 70 kV (or 35 kV) using the 100 kV (or 35 kV) pulser. An ion implantation doping approach is used to create “dead bands” in GaAs PCSS that solved the “lightning- like” filamentary current conduction issue. High gain photoconductions was produced when irradiated with the laser energy on the order of about 1 mJ.

The undoped GaAs sample has been tested using an 18 kV DC charged LCR circuit and produced conduction currents as high as several hundred amperes.

Since the doped GaAs samples have about 10 MΩ across the anode-cathode gap (due to the Ag and/or O ion beam irradiation), the DC LCR circuit was not suitable to use in the testing. A pulse charged circuit and a 35 kV, about 60 ns pulser was used to produce up to 12 uniform distributed conduction current channels. Trigger laser energy is on the order of 1 mJ.

It is noted that the terms “substantially” and “about” are utilized herein to represent the degree by which a quantitative representation may vary from a stated reference without resulting in a change in the basic function of the subject matter at issue. They may also (in certain contexts) be utilized to represent the inherent degree of uncertainty that may be attributed to any quantitative comparison, value, measurement, or other representation.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed:

1. A photoconductive semiconductor switch comprising a photoconductive substrate having a pair of spaced metal contacts on a surface thereof, the space between the metal contacts constituting a switching gap, the switching gap having a plurality of spaced lateral current flow preventing channels therein, the lateral current flow preventing channels being formed by ion implantation of the semiconductor substrate in the area of the lateral current flow preventing channels, the channels extending the distance from one spaced contact to the other; at least one conducting channel in the space between two of the spaced lateral flow preventing channels which conducts a current when the switch is irradiated with a proton source.

2. The switch of claim 1 wherein the substrate is GaAs.

3. The switch of claim 2 wherein the GaAs substrate is formed from single crystals with a resistivity greater than about 10⁷ Ohm-cm.

4. The switch of claim 2 wherein the ion implanted channels prevent lateral current flow at and in the vicinity of the surface of the substrate.

5. The switch of claim 4 wherein the ion implanted channel is implanted with oxygen ions.

6. The switch of claim 1 wherein the switch exhibits a current density greater than about 1000 A/cm².

7. The switch of claim 5 wherein the ion implanted channels are about 100-700μ wide.

8. The switch of claim 7 wherein the ion implanted channels are about 200-500μ wide.

9. The switch of claim 1 wherein the contact comprises a lamina of Ni, Ge, and Au layers or Ni, Si and Au layers in order from the surface of the GaAs substrate.

10. The switch of claim 7 wherein the ions are implanted to a depth sufficient to prevent lateral current flow.

11. The switch of claim 9 wherein the contact is a lamina formed of layers of Ni/Ge/Au in order from the substrate.

12. The switch of claim 1 wherein the channels are parallel to each other and run from one contact to the other contact.

13. The switch of claim 11 wherein the contacts are annealed.

14. A photoconductive semiconductor switch comprising a photoconductive GaAs substrate having a pair of spaced metal contacts on a surface thereof, the space between the metal contacts constituting a switching gap, the switching gap having a plurality of spaced lateral current flow preventing channels therein, the lateral current flow preventing channels being formed by ion implantation of the GaAs substrate in the channels, the channels running from one spaced contact to the other; at least one conducting channel between two of the lateral flow preventing channels; and a trigger.

15. The switch of claim 14 wherein the trigger is a laser.

16. The switch of claim 15 wherein the laser operates at an energy less than about 10 μJ.

17. The switch of claim 15 wherein the laser is a semiconductor diode laser.

18. The switch of claim 15 wherein the laser operates the switch in a linear mode.

19. The switch of claim 15 wherein the laser operates the switch in a nonlinear mode.

20. The switch of claim 15 wherein the laser operates a an energy greater than or equal to about 1 mJ.
